(19) United States
(12) Patent Application Publication
(10) Pub. No.: US 2025/0248106 A1
(43) Pub. Date: Jul. 31, 2025

(54) METHOD OF MANUFACTURING SEMICONDUCTOR DEVICE

(71) Applicant: Renesas Electronics Corporation, Tokyo (JP)

(72) Inventors: Yotaro GOTO, Tokyo (JP); Atsushi SAKAI, Tokyo (JP); Fumitoshi TAKAHASHI, Tokyo (JP)

(21) Appl. No.: 18/949,055

(22) Filed: Nov. 15, 2024

(30) Foreign Application Priority Data
Jan. 31, 2024 (JP) 2024-013479

(51) Int. Cl. H01L 21/8234; H01L 21/266; H01L 29/66

(52) U.S. Cl. CPC H10D 84/038; H01L 21/266; H10D 30/0285; H10D 64/017; H10D 84/0151

(57) ABSTRACT

A resist pattern having an opening portion that exposes a part of a conductive film located on a gate insulating film is formed on the conductive film. Next, an anisotropic etching treatment is performed using the resist pattern as a mask to selectively remove the conductive film exposed from the resist pattern and to form a gate pattern and a dummy gate pattern from the remaining conductive film. Next, an oblique ion implantation is performed using the resist pattern as a mask to form a p-type body region in a semiconductor substrate.

### CROSS-REFERENCE TO RELATED APPLICATIONS

The disclosure of Japanese Patent Application No. 2024-013479 filed on Jan. 31, 2024, including the specification, drawings and abstract is incorporated herein by reference in its entirety.

### BACKGROUND

The present invention relates to a method of manufacturing a semiconductor device.

There are disclosed techniques listed below.

[Patent Document 1] Japanese Unexamined Patent Application Publication No. 2019-192741

As disclosed in Patent Document 1, a Laterally Diffused Metal Oxide Semiconductor (LDMOS), which is a kind of Metal Insulator Semiconductor Field Effect Transistor (MISFET), is known to have a low concentration drift region disposed between a high concentration drain region and a gate electrode.

In a semiconductor device including a plurality of LDMOSs, LDMOSs are symmetrically arranged around the axis of the drain region and the source region, with adjacent LDMOS sharing a drain region or a source region.

Furthermore, a method has been performed where a conductive film for gate electrodes is patterned as a gate pattern, and the resist pattern used for the patterning is used as is for a mask to perform oblique ion implantation. Thereby, a body region configuring the channel region of the LDMOS is formed between adjacent gate patterns. Subsequently, a source region is formed in the body region.

### SUMMARY

In the outermost LDMOS among the plurality of LDMOS, the drain region is shared with the LDMOS adjacent to the outermost LDMOS, but the body region and the source region are not shared with other LDMOS. Therefore, in the outermost LDMOS, the body region is formed using only one gate pattern as a mask. Consequently, the impurity profile of the body region of the outermost LDMOS may differ from the impurity profile of the body regions of other LDMOS.

As a result, for example, the threshold voltage of the outermost LDMOS may be lower than the threshold voltage of other LDMOS, making it easier for leak current to flow in the outermost LDMOS than in other LDMOS. Therefore, there is a concern that the reliability of the semiconductor device may decrease.

Other problems and novel features will become apparent from the description of this specification and the accompanying drawings.

In one embodiment, a manufacturing method of a semiconductor device includes a step of forming an element isolation portion in a semiconductor substrate, a step of forming a gate insulating film on the semiconductor substrate, a step of forming a first conductive film on the gate insulating film and the element isolation portion, a step of forming a first resist pattern on the first conductive film, a step of performing anisotropic etching treatment using the first resist pattern as a mask to selectively remove the first conductive film exposed from the first resist pattern and to form a first gate pattern and a dummy gate pattern from the first conductive film, and a step of performing oblique ion implantation using the first resist pattern as a mask to form a first body region of a first conductivity type in the semiconductor substrate.

According to one embodiment, the reliability of the semiconductor device can be improved.

### BRIEF DESCRIPTION OF THE DRAWINGS

FIG. 1 is a plan view showing a semiconductor device according to a first embodiment.

FIG. 2 is an enlarged plan view showing a part of FIG. 1.

FIG. 3 is a cross-sectional view showing the semiconductor device according to the first embodiment.

FIG. 4 is an enlarged cross-sectional view showing a part of FIG. 3.

FIG. 5 is a cross-sectional view showing a manufacturing step of the semiconductor device according to the first embodiment.

FIG. 6 is a cross-sectional view showing a manufacturing step of the semiconductor device following FIG. 5.

FIG. 7 is a cross-sectional view showing a manufacturing step of the semiconductor device following FIG. 6.

FIG. 8 is a cross-sectional view showing a manufacturing step of the semiconductor device following FIG. 7.

FIG. 9 is a cross-sectional view showing a manufacturing step of the semiconductor device following FIG. 8.

FIG. 10 is a cross-sectional view showing a manufacturing step of the semiconductor device following FIG. 8.

FIG. 11 is a cross-sectional view showing a manufacturing step of the semiconductor device following FIG. 9.

FIG. 12 is a cross-sectional view showing a manufacturing step of the semiconductor device following FIG. 11.

FIG. 13 is a cross-sectional view showing a manufacturing step of the semiconductor device following FIG. 12.

FIG. 14 is a cross-sectional view showing a manufacturing step of the semiconductor device following FIG. 13.

FIG. 15 is a cross-sectional view showing a manufacturing step of the semiconductor device following FIG. 14.

FIG. 16 is a cross-sectional view showing a manufacturing step of the semiconductor device following FIG. 15.

FIG. 17 is a cross-sectional view for explaining oblique ion implantation of FIG. 11.

FIG. 18 is a graph showing experimental data by the present inventors.

FIG. 19 is a cross-sectional view showing a manufacturing step of a semiconductor device according to a first modified example.

FIG. 20 is a cross-sectional view showing a semiconductor device according to a second modified example.

FIG. 21 is a main portion cross-sectional view showing a manufacturing step of the semiconductor device according to the second modified example.

FIG. 22 is a main portion cross-sectional view showing a manufacturing step of the semiconductor device according to the second modified example.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

Furthermore, the X direction, Y direction, and Z direction described in this application intersect each other and are orthogonal to each other. In this application, the Z direction is described as the vertical direction, depth direction, or thickness direction of a certain structure. The expressions “plan view” or “planar view” used in this application mean that the plane constituted by the X direction and Y direction is regarded as the “plane,” and this “plane” is viewed from the Z direction.

### FIRST EMBODIMENT

### Structure of Semiconductor Device

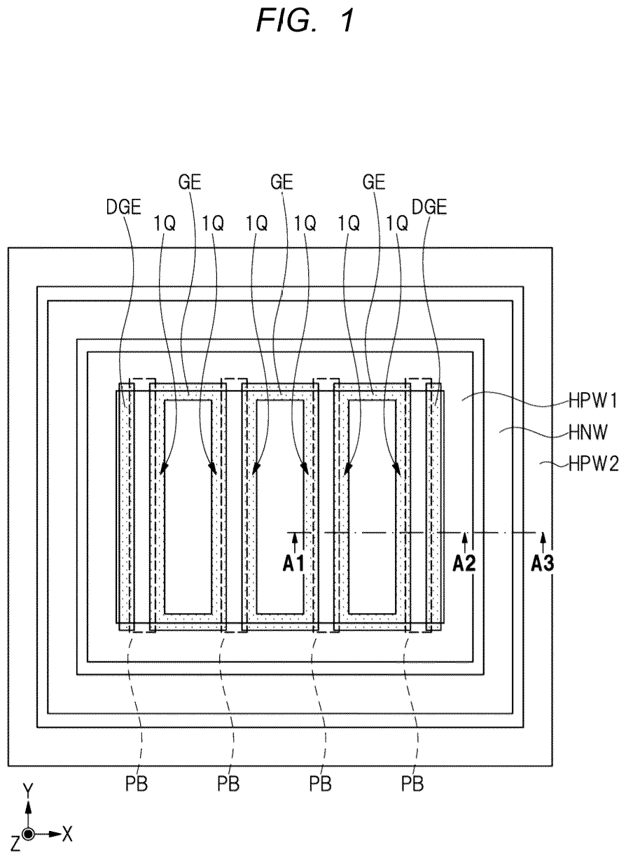

As shown in FIG. 1, a semiconductor device includes a plurality of n-type MISFETs 1Q each having a gate electrode GE, two dummy gate electrodes DGE, a p-type well region (impurity region) HPW1, an n-type well region (impurity region) HNW, and a p-type well region (impurity region) HPW2. The well region HPW1, the well region HNW, and the well region HPW2 extend in the X direction and the Y direction so as to surround the plurality of MISFETs 1Q and the two dummy gate electrodes DGE in plan view. The well region HNW surrounds the well region HPW1 in plan view. The well region HPW2 surrounds the well region HNW in plan view.

Although not shown here, an element isolation portion STI also extends in the X direction and the Y direction so as to surround the plurality of MISFETs 1Q in plan view. The two dummy gate electrodes DGE are formed on the element isolation portion STI extending in the Y direction, respectively.

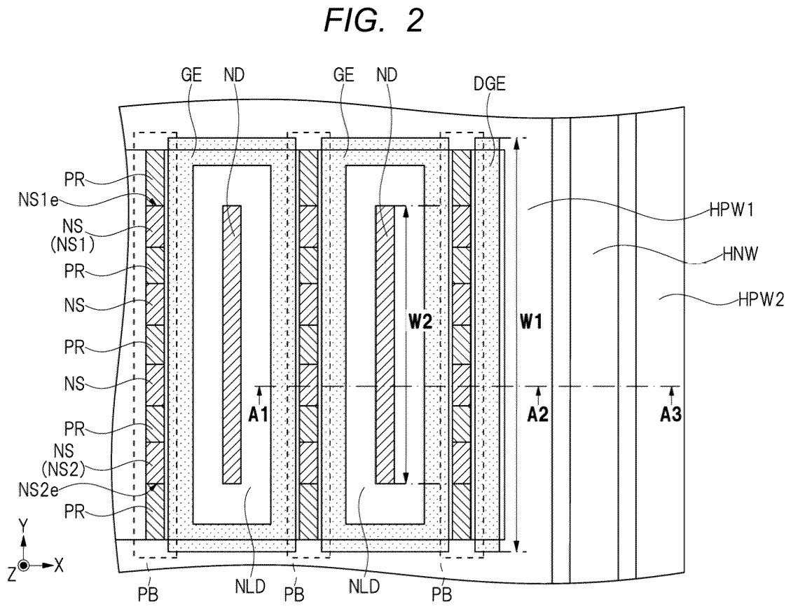

As shown in FIG. 2, the plurality of MISFETs 1Q each have the gate electrode GE, a p-type body region (impurity region) PB, an n-type source region (impurity region) NS, a p-type high concentration diffusion region (impurity region) PR, an n-type drift region (impurity region) NLD, and an n-type drain region (impurity region) ND. The gate electrode GE is formed of, for example, an n-type polycrystalline silicon film. The high concentration diffusion region PR has a higher impurity concentration than the body region PB. The drift region NLD has a lower impurity concentration than the drain region ND and the source region NS.

The gate electrode GE, the body region PB, the drain region ND, and the dummy gate electrode DGE extend in the Y direction. The plurality of source regions NS is formed in the body region PB so as to be separated from each other in the Y direction. Between the source regions NS adjacent to each other in the Y direction, the high concentration diffusion region PR is formed, respectively. The part of the body region PB that is located between the drain region ND and the source region NS and overlaps the gate electrode GE in plan view functions as the channel region of the MISFET 1Q.

The plurality of MISFETs 1Q are arranged symmetrically around the axis of the drain region ND and the source region NS. In the MISFETs 1Q adjacent to each other in the X direction, either the drain region ND or the source region NS is shared. In the outermost MISFET 1Q among the plurality of MISFETs 1Q, the drain region ND is shared with the MISFET 1Q adjacent to the outermost MISFET 1Q, but the body region PB and the source region NS are not shared with other MISFETs 1Q.

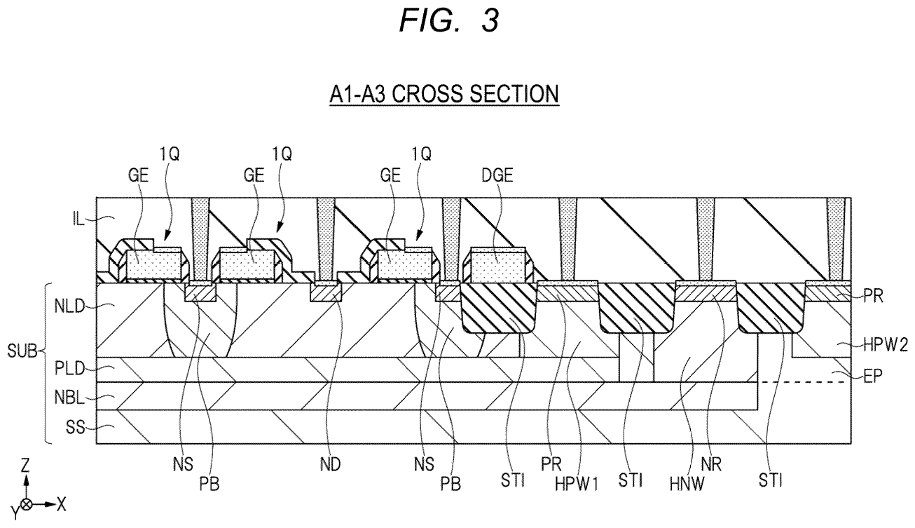

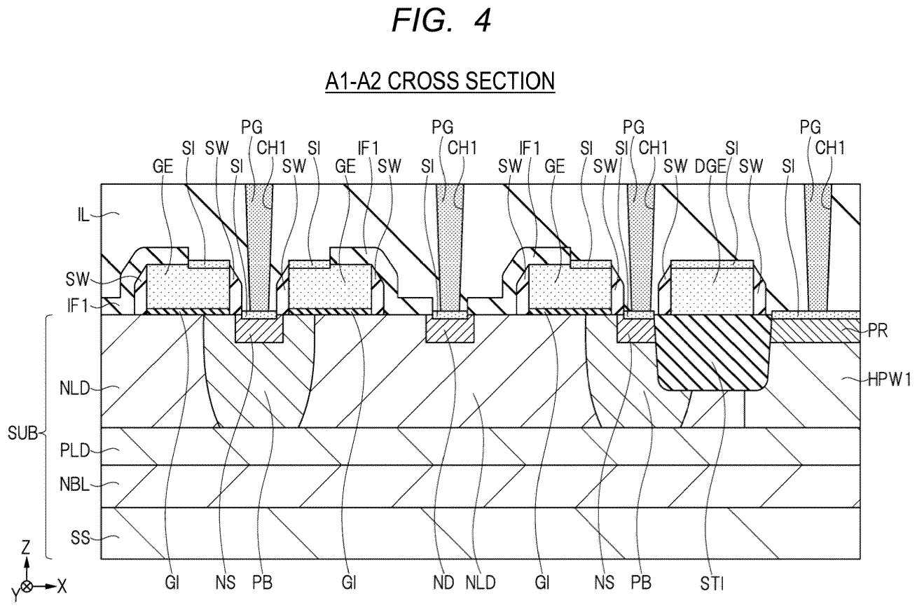

FIG. 3 is a cross-sectional view along the line A1-A3 shown in FIGS. 1 and 2. FIG. 4 is a cross-sectional view along the line A1-A2 shown in FIGS. 1 and 2 and shows a part of FIG. 3 in an enlarged manner.

A semiconductor substrate SUB is formed of p-type silicon. In the first embodiment, the semiconductor substrate SUB includes a support substrate SS made of, for example, a p-type silicon substrate, and a p-type semiconductor layer (silicon layer) EP formed on the support substrate SS by epitaxial growth. In the following description, various impurity regions formed in the semiconductor substrate SUB are specifically formed in the semiconductor layer EP.

In the semiconductor substrate SUB, the element isolation portion STI is formed. The element isolation portion STI includes a trench formed in the semiconductor substrate SUB to reach a predetermined depth from the upper surface of the semiconductor substrate SUB, and an insulating film buried in the trench. The insulating film is, for example, a silicon oxide film.

In the semiconductor substrate SUB, the n-type drift region NLD, a p-type impurity region PLD, and an n-type buried region NBL are formed. The drift region NLD is formed to a predetermined depth from the upper surface of the semiconductor substrate SUB and is located on the impurity region PLD and the buried region NBL. The impurity region PLD is located on the buried region NBL. The impurity region PLD and the buried region NBL are formed in the semiconductor substrate SUB at a position deeper than the element isolation portion STI.

Furthermore, in the semiconductor substrate SUB, the body region PB, the well region HPW1, the well region HNW, and the well region HPW2 are formed. The body region PB, the well region HPW1, the well region HNW, and the well region HPW2 are formed to a position deeper than the element isolation portion STI from the upper surface of the semiconductor substrate SUB. The body region PB and the well region HPW1 are in contact with the impurity region PLD. The buried region NBL is in contact with the well region HNW.

On the semiconductor substrate SUB, a gate insulating film GI is formed. The gate insulating film GI is, for example, a silicon oxide film. On the gate insulating film GI, the gate electrode GE is formed. On the side surface of the gate electrode GE, a sidewall spacer SW is formed. The sidewall spacer SW includes, for example, a silicon oxide film and a nitride silicon film formed on the oxide silicon film. An insulating film IF1 is formed on the upper surface of the semiconductor substrate SUB to cover a part of the gate electrode GE and the sidewall spacer SW. The insulating film IF1 is, for example, a silicon oxide film.

In the body region PB, the source region NS is formed. As shown in FIG. 2, the high concentration diffusion region PR is also formed in the body region PB. In the drift region NLD, the drain region ND is formed. A part of the drain region ND and the drift region NLD are covered with the insulating film IF1, but other parts of the drain region ND are exposed from the insulating film IF1.

The gate electrode GE is formed on a portion of the semiconductor substrate SUB located between the source region NS and the drain region ND in the X direction. A portion of the body region PB located between the source region NS and the drain region ND and located under the gate electrode GE, functions as a channel region of MISFET 1Q.

In the well region HPW1 and the well region HPW2, the high concentration diffusion region PR is formed. In the well region HNW, an n-type high concentration diffusion region (impurity region) NR is formed. The impurity concentration of each of the source region NS, the drain region ND, and the high concentration diffusion region NR is higher than the impurity concentration of the drift region NLD. The impurity concentration of the high concentration diffusion region PR is higher than the impurity concentration of each of the well region HPW1 and the well region HPW2.

On a portion exposed from the insulating film IF1 of the semiconductor substrate SUB, a silicide film SI is formed. That is, on the upper surface of a part of the gate electrode GE, the source region NS, the drain region ND, the high concentration diffusion region PR, and the high concentration diffusion region NR, the silicide film SI is formed. The source region NS and the high concentration diffusion region PR formed in the body region PB are electrically connected by the same silicide film SI. The silicide film SI is, for example, a cobalt silicide (CoSi₂) film, a nickel silicide (NiSi) film, or a nickel platinum silicide (NiPtSi) film.

On the upper surface of the semiconductor substrate SUB, an interlayer insulating film IL is formed. The interlayer insulating film IL is, for example, a silicon oxide film. In the interlayer insulating film IL, a plurality of holes CH1 are formed. In each of the plurality of holes CH1, a plug PG is formed. The plug PG includes, for example, a barrier metal film and a conductive film formed on the barrier metal film. The barrier metal film includes, for example, a titanium film and a titanium nitride film, and the conductive film is, for example, a tungsten film.

The plurality of holes CH1 are formed so as to reach the source region NS, the drain region ND, the high concentration diffusion region PR, and the high concentration diffusion region NR. Although not shown here, on the interlayer insulating film IL, a plurality of wirings connected to the plurality of plugs PG are formed. A predetermined potential is supplied to the source region NS, the drain region ND, the high concentration diffusion region PR, and the high concentration diffusion region NR from the plurality of wirings.

The drain region ND and the drift region NLD are each conducted as an n-type impurity region and are fixed at the same potential. The well region HPW1, the impurity region PLD, the body region PB, the high concentration diffusion region PR formed in the well region HPW1, and the high concentration diffusion region PR formed in the body region PB are each conducted as a p-type impurity region and are fixed at the same potential. The well region HPW2, the semiconductor layer EP, the support substrate SS, and the high concentration diffusion region PR formed in the well region HPW2 are each conducted as a p-type impurity region and are fixed at the same potential.

The high concentration diffusion region NR, the well region HNW, and the buried region NBL are each conducted as an n-type impurity region and are fixed at the same potential. By electrically isolating the plurality of MISFETs 1Q and the semiconductor substrate SUB using the buried region NBL and the well region HNW, the noise resistance of the plurality of MISFETs 1Q can be enhanced.

Although not shown here, the hole CH1 and the plug PG are also formed on the upper surface of the gate electrode GE, on which the silicide film SI is formed. During the operation of MISFET 1Q, a gate potential is supplied to the gate electrode GE, a drain potential is supplied to the drain region ND, and a source potential is supplied to the source region NS.

Furthermore, the dummy gate electrode DGE is formed on the element isolation portion STI, where the body region PB and the well region HPW1 are in contact. Although the silicide film SI is formed on the upper surface of the dummy gate electrode DGE, the hole CH1 and the plug PG are not formed on the upper surface of the dummy gate electrode DGE. Therefore, the dummy gate electrode DGE is not electrically connected to any wiring, and no potential is supplied to the dummy gate electrode DGE. That is, the dummy gate electrode DGE is in an electrically floating state.

### Manufacturing Method of Semiconductor Device

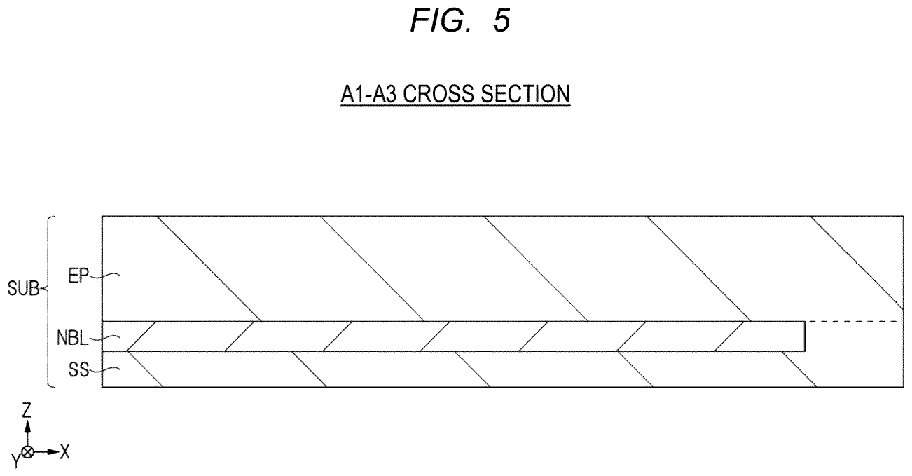

Hereinafter, each manufacturing step included in the manufacturing method of the semiconductor device in the first embodiment will be described using FIGS. 5 to 15.

As shown in FIG. 5, the semiconductor substrate SUB is prepared. The semiconductor substrate SUB may be a single layer of p-type silicon substrate, but in the first embodiment, the semiconductor substrate SUB includes the support substrate SS and the semiconductor layer EP. First, the support substrate SS is prepared. The support substrate SS is made of p-type silicon. Next, the semiconductor layer EP, which is a p-type silicon layer, is formed on the support substrate SS by epitaxial growth.

Next, the buried region NBL is formed in the semiconductor substrate SUB by photolithography and ion implantation. After forming the buried region NBL in the support substrate SS, the semiconductor layer EP may be formed on the support substrate SS.

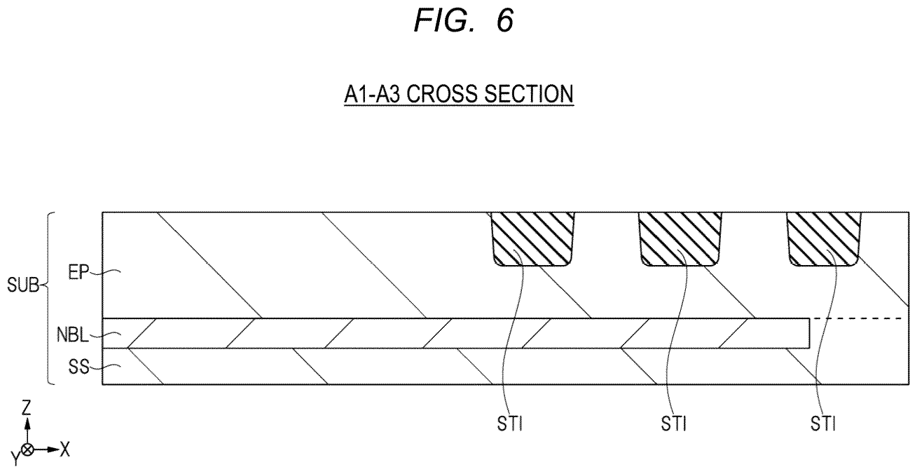

As shown in FIG. 6, the element isolation portion STI is formed in the semiconductor substrate SUB. First, a trench is formed in the semiconductor substrate SUB to a predetermined depth from the upper surface of the semiconductor substrate SUB by photolithography and anisotropic etching treatment. Next, an insulating film such as a silicon oxide film is formed on the semiconductor substrate SUB so as to fill the trench. Next, the insulating film buried in the trench remains, and the insulating film located outside the trench is removed by polishing using the CMP method.

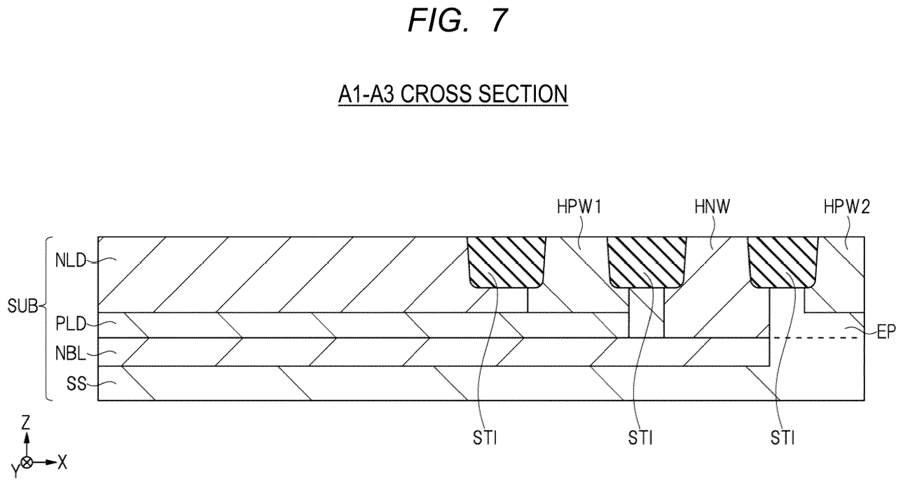

As shown in FIG. 7, the impurity region PLD, the drift region NLD, the well region HPW1, the well region HPW2, and the well region HNW are sequentially formed in the semiconductor substrate SUB by photolithography and ion implantation. The order of forming these may be in any sequence.

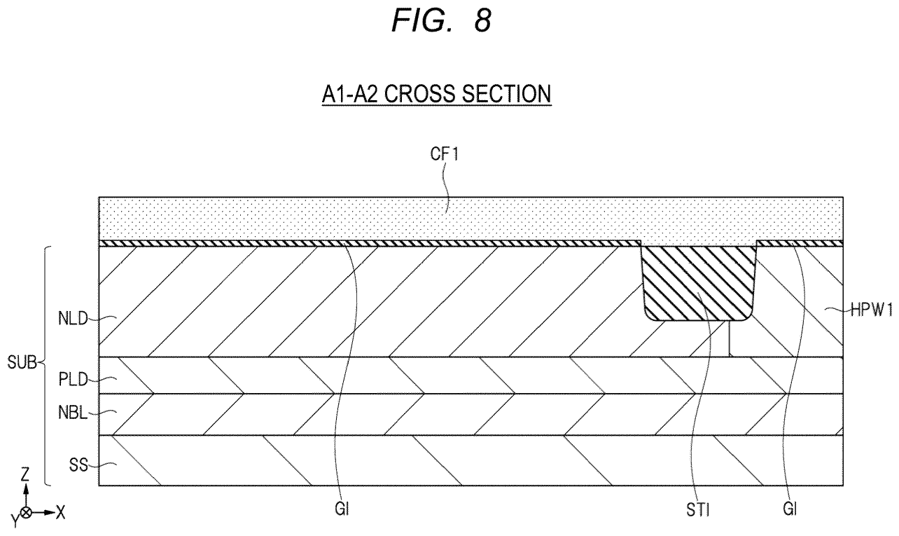

As shown in FIG. 8, first, for example, the gate insulating film GI is formed on the semiconductor substrate SUB by thermal oxidation treatment. Next, for example, a conductive film CF1 is formed on the gate insulating film GI and on the element isolation portion STI by a film formation process using the CVD method. The conductive film CF1 is, for example, a polycrystalline silicon film into which n-type impurities have been introduced.

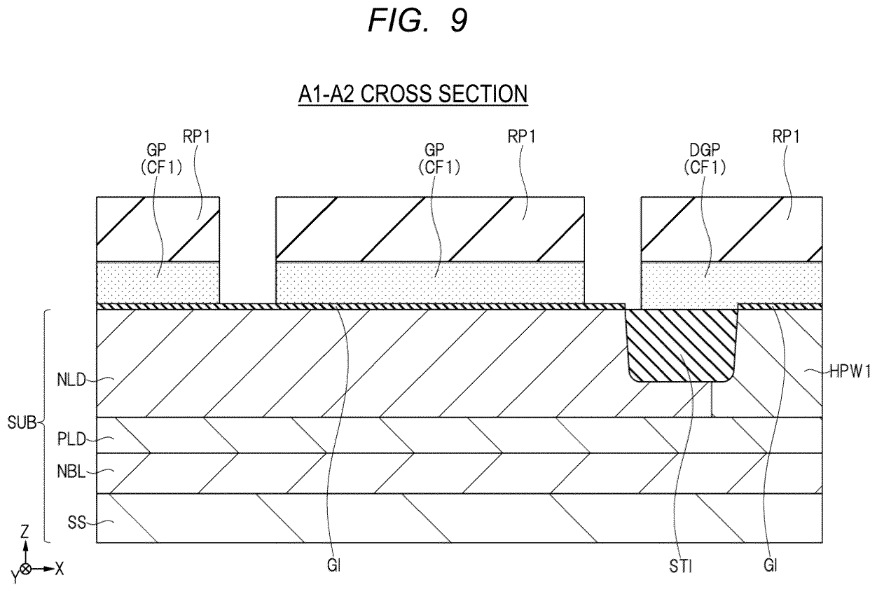

As shown in FIG. 9, first, a resist pattern RP1 is formed on the conductive film CF1. The resist pattern RP1 has an opening portion that exposes a part of the conductive film CF1 located on the gate insulating film GI, the boundary between the element isolation portion STI and the semiconductor substrate SUB, and a part of the conductive film CF1 located on the element isolation portion STI.

Next, by performing an anisotropic etching treatment using the resist pattern RP1 as a mask, the conductive film CF1 exposed from the resist pattern RP1 is selectively removed to form a gate pattern GP and a dummy gate pattern DGP from the conductive film CF1. The dummy gate pattern DGP is located at least on the element isolation portion STI.

As shown in FIG. 9, the resist pattern RP1 also has opening portions that expose a plurality of locations of the conductive film CF1 located on the gate insulating film GI, and the plurality of gate patterns GP are formed by the anisotropic etching treatment.

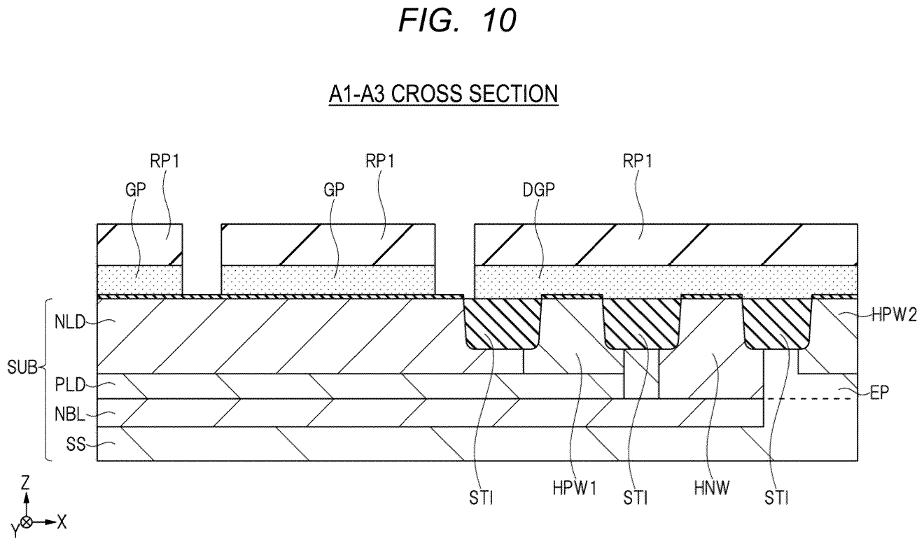

FIG. 10 is a cross-sectional view along lines A1-A3 showing the state after the anisotropic etching treatment. As shown in FIG. 10, the well region HPW1, the well region HNW, and the well region HPW2 are covered by the dummy gate pattern DGP and the resist pattern RP1. Therefore, no body region PB is formed in the well region HPW1, the well region HNW, and the well region HPW2 due to the subsequent oblique ion implantation.

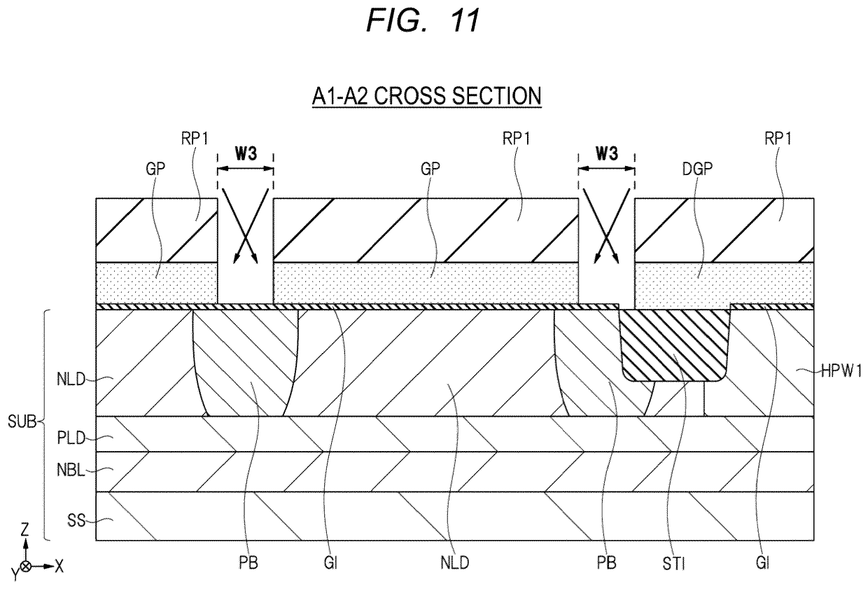

As shown in FIG. 11, the body region PB is formed by performing oblique ion implantation using the resist pattern RP1 as a mask. In this oblique ion implantation, ions are implanted from a direction tilted at an angle of, for example, more than 20 degrees and less than 45 degrees with respect to the direction perpendicular (Z direction) to the upper surface of the semiconductor substrate SUB.

The body region PB is formed in a part of the semiconductor substrate SUB located between the gate pattern GP and the dummy gate pattern DGP in plan view, and in a part of the semiconductor substrate SUB located between the plurality of gate patterns GP in plan view. Furthermore, the body region PB is also formed in a part of the semiconductor substrate SUB located under each gate pattern GP. Subsequently, the resist pattern RP1 is removed by ashing.

The opening width W3 of the plurality of opening portions of the resist pattern RP1 is the same as each other. The opening width W3 is the width in the direction in which the plurality of gate patterns GP and the dummy gate pattern DGP are adjacent to each other, and it is the width in the X direction. Therefore, after the anisotropic etching treatment of FIG. 9, the shortest distance between the plurality of gate patterns GP is the same as each other, and it is also the same as the shortest distance between the gate pattern GP and the dummy gate pattern DGP.

Since the oblique ion implantation is performed using the same resist pattern RP1, the plurality of body regions PB are formed self-aligned. Therefore, the width of the areas where the body region PB and the gate pattern GP overlap each other in plan view is constant under each gate pattern GP.

That is, by performing the anisotropic etching treatment for the conductive film CF1 and the ion implantation for the body region PB using the same resist pattern RP1, the variation in channel length of the plurality of MISFETs 1Q can be suppressed.

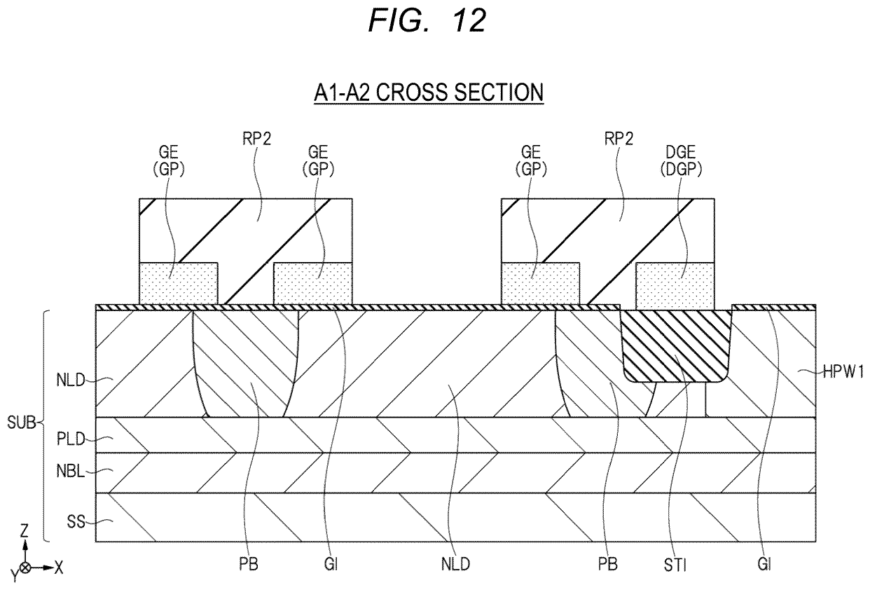

As shown in FIG. 12, first, a resist pattern RP2 is formed to cover a part of the gate pattern GP located on the gate insulating film GI, the body region PB, and a part of the dummy gate pattern DGP located on the element isolation portion STI.

Subsequently, by using the resist pattern RP2 as a mask and performing anisotropic etching treatment, the gate pattern GP and the dummy gate pattern DGP exposed from the resist pattern RP2 are selectively removed to form the gate electrode GE from the gate pattern GP and the dummy gate electrode DGE from the dummy gate pattern DGP. Thereafter, the resist pattern RP2 is removed by ashing.

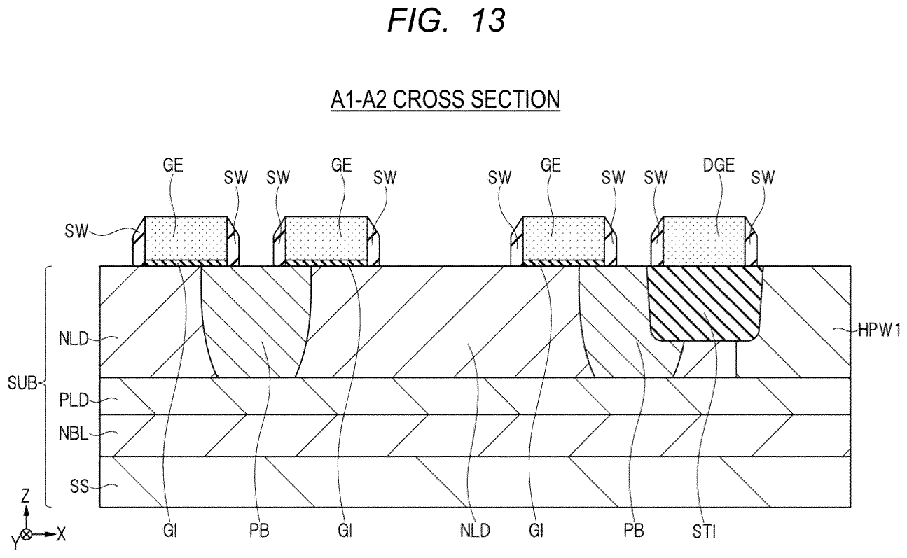

As shown in FIG. 13, on each side surface of the gate electrode GE and the dummy gate electrode DGE, the sidewall spacer SW is formed. First, for example, a laminated film including a silicon oxide film, and a nitride silicon film is formed on the semiconductor substrate SUB to cover the gate electrode GE and the dummy gate electrode DGE, for example, by a film formation process using CVD method. Next, by performing anisotropic etching treatment on the laminated film, the sidewall spacer SW is formed from the laminated film remaining on each side surface of the gate electrode GE and the dummy gate electrode DGE. Note that the gate insulating film GI exposed from the gate electrode GE is also removed by the anisotropic etching treatment.

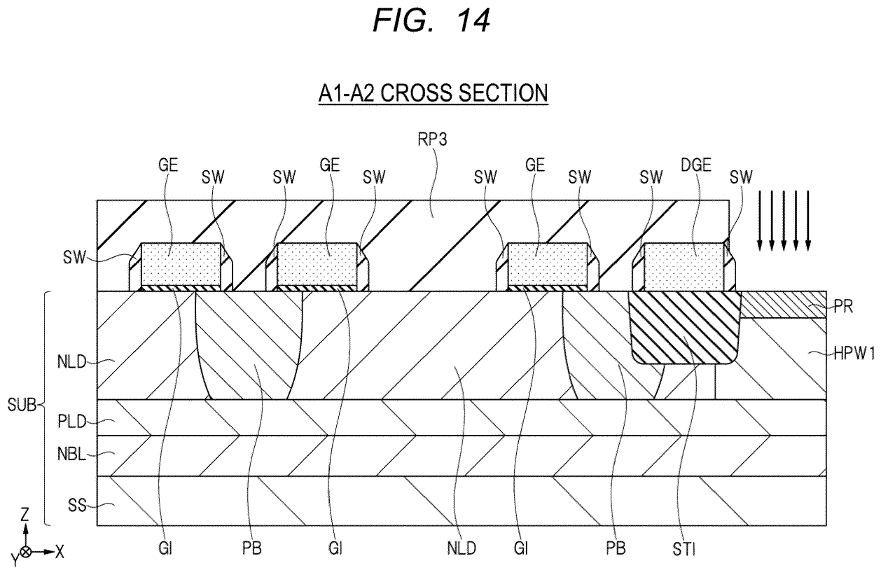

As shown in FIG. 14, first, a resist pattern RP3 having an opening portion that exposes the well region HPW1 is formed. Although not shown, the resist pattern RP3 also has an opening portion that exposes a part of the body region PB and the well region HPW2. Next, by using the resist pattern RP3 as a mask and performing ion implantation, the high concentration diffusion region PR is formed in the well region HPW1, in the body region PB, and in the well region HPW2 (refer to FIGS. 2 and 3). Thereafter, the resist pattern RP3 is removed by ashing.

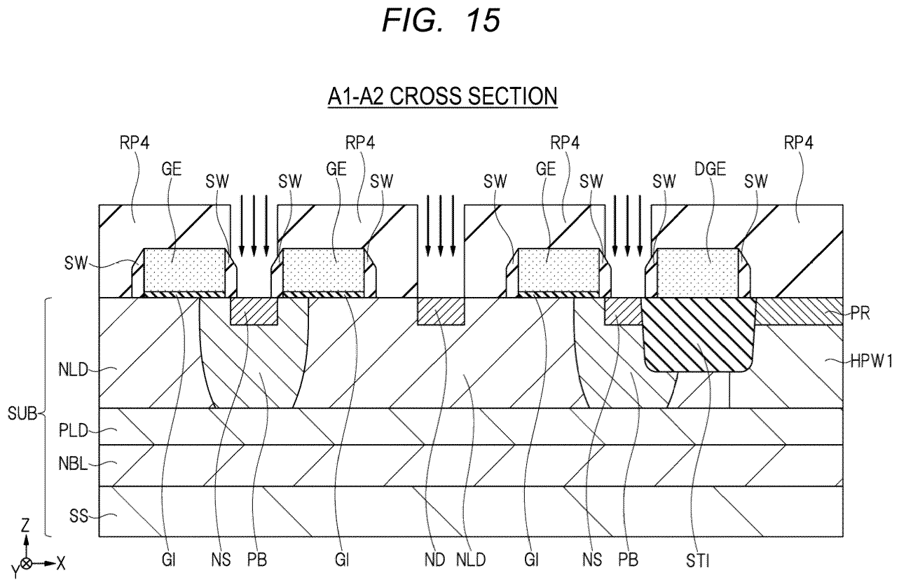

As shown in FIG. 15, first, a resist pattern RP4 having an opening portion that exposes a part of the body region PB and a part of a drift region NLD is formed. Although not shown, the resist pattern RP4 also has an opening portion that exposes the well region HNW. Next, by using the resist pattern RP4 as a mask and performing ion implantation, the source region NS is formed in the body region PB, the drain region ND is formed in the drift region NLD, and the high concentration diffusion region NR is formed in the well region HNW (refer to FIG. 3). Note that the drain region ND is formed in the semiconductor substrate SUB at a position away from each gate electrode GE. Thereafter, the resist pattern RP4 is removed by ashing.

The ion implantation of FIG. 14 and the ion implantation of FIG. 15 may be performed in any order. After these ion implantations, a heat treatment is performed on the semiconductor substrate SUB to activate the impurities included in each impurity region.

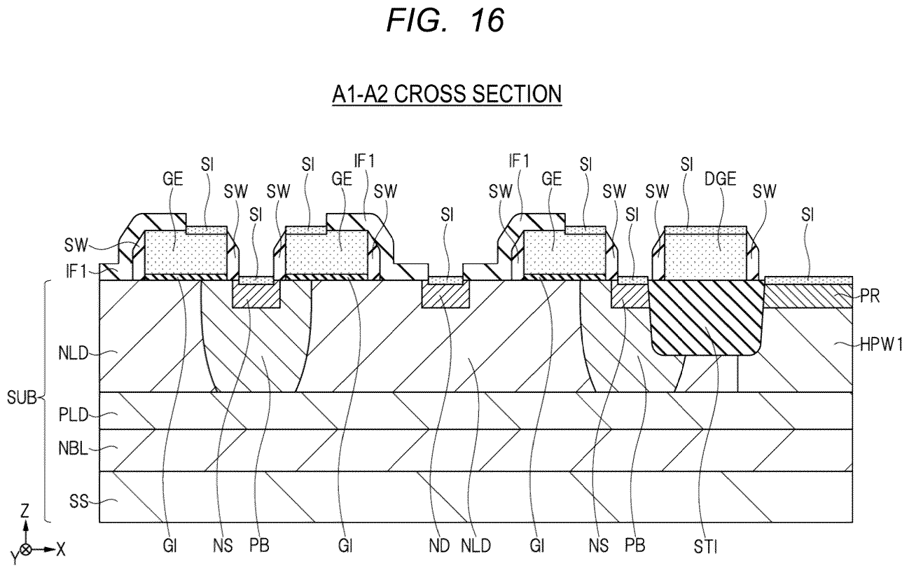

As shown in FIG. 16, first, for example, by a film formation process using CVD method, the insulating film IF1 is formed on the upper surface of the semiconductor substrate SUB to cover the gate electrode GE, the dummy gate electrode DGE, and the sidewall spacer SW. Next, the insulating film IF1 is patterned by photolithography technique and anisotropic etching treatment. Accordingly, the insulating film IF1 remains on a part of the drain region ND, on the drift region NLD, on the sidewall spacer SW, and on a part of the upper surface of the gate electrode GE.

Next, by using salicide technique, the silicide film SI is formed on the upper surfaces of the gate electrode GE, the dummy gate electrode DGE, the drain region ND, the source region NS, and the high concentration diffusion region PR, each of which is exposed from the insulating film IF1. Although not shown, the silicide film SI is also formed on the upper surface of the high concentration diffusion region NR.

Thereafter, through the following manufacturing steps, the semiconductor device shown in FIGS. 3 and 4 is manufactured.

First, for example, by using a CVD method for film formation, the interlayer insulating film IL is formed on the upper surface of the semiconductor substrate SUB. Next, by using photolithography technique and anisotropic etching treatment, the plurality of holes CH1 are formed in the interlayer insulating film IL. Each of the plurality of holes CH1 reaches the silicide film SI formed on the upper surfaces of the source region NS, the drain region ND, the high concentration diffusion region PR, the high concentration diffusion region NR, and the gate electrode GE.

Next, the plug PG is formed in each of the plurality of holes CH1. To form the plug PG, first, a barrier metal film is formed in the plurality of holes CH1 and on the interlayer insulating film IL, for example, by sputtering. The barrier metal film includes, for example, a titanium film and a titanium nitride film. Next, for example, a conductive film such as a tungsten film is formed on the barrier metal film by, for example, a CVD method. Then, the conductive film and the barrier metal film formed outside the plurality of holes CHI are removed by, for example, a CMP method for polishing.

### Main Features of First Embodiment

The main feature of the first embodiment is that, as shown in FIG. 11, oblique ion implantation for the body region PB is performed in a state where the dummy gate pattern DGP is formed.

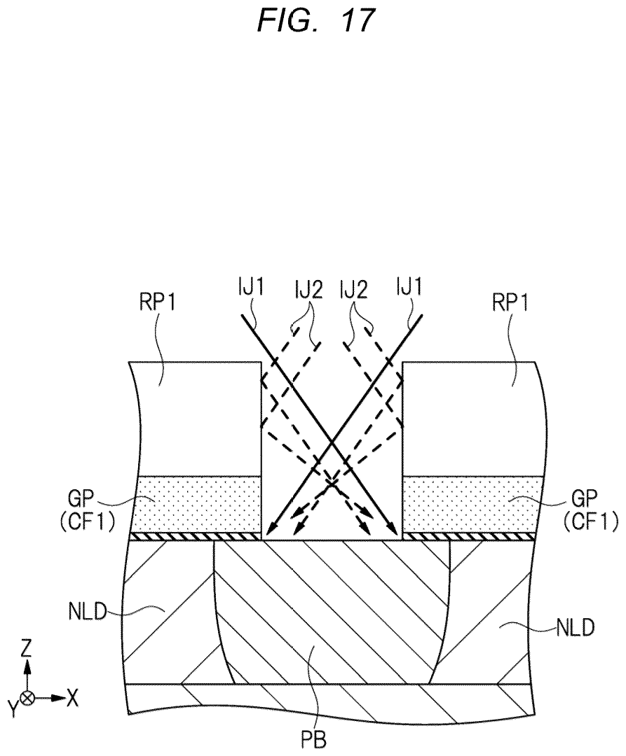

As shown in FIG. 17, in the oblique ion implantation, there are ions IJ1 that are directly injected into the drift region NLD and ions IJ2 that are injected into the drift region NLD after being reflected or scattered by the resist pattern RP1. Therefore, when the opening width of the resist pattern RP1 changes, the injection position of the ions IJ2 changes, and the impurity profile of the body region PB changes. As described above, the part of the body region PB located under the gate pattern GP functions as the channel region of the MISFET 1Q. However, the change in the opening width of the resist pattern RP1 changes the impurity profile of the channel region, and the threshold voltage of the MISFET 1Q changes.

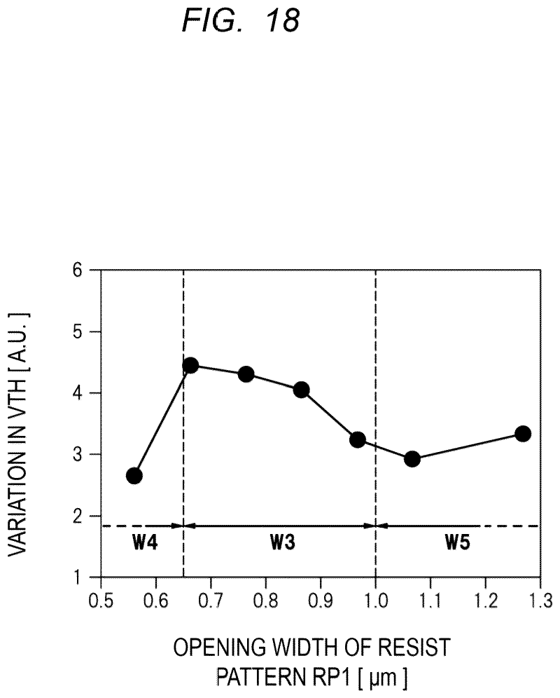

FIG. 18 shows the relationship between the opening width of the resist pattern RP1 and the variation in the threshold voltage (Vth) of the MISFET 1Q. As shown in FIG. 18, the opening width W3 is, for example, 0.65 μm or more and 1.0 μm or less, and is used in the resist pattern RP1 described in FIG. 11. The opening width W4 is smaller than the opening width W3, for example, less than 0.65 μm. The opening width W5 is greater than the opening width W3, for example, wider than 1.0 μm. The opening width W3, the opening width W4, and the opening width W5 are widths in the X direction, respectively.

In the case of the opening width W4, a portion of the ions IJ1 and IJ2 being injected is blocked by the upper surface of the resist pattern RP1. As a result, the number of ions injected into the channel region decreases, leading to a reduction in threshold voltage. In the case of the opening width W3, compared to the case of opening width W4, the ions IJ1 and IJ2 are more likely to reach the channel region, resulting in an increase in threshold voltage. In the case of the opening width W5, compared to the case of opening width W3, the number of ions IJ2 that can reach the channel region decreases, leading to a reduction in threshold voltage. The MISFET 1Q with a reduced threshold voltage is formed as a semiconductor element that is more likely to flow leakage current than other MISFET 1Qs, which may decrease the reliability of the semiconductor device.

As shown in FIG. 1, in the first embodiment, the dummy gate electrode DGE is formed on the further outside of the MISFET 1Q located at the outermost in the X direction (outermost MISFET 1Q). The dummy gate electrode DGE and the dummy gate pattern DGP which is base of the dummy gate electrode DGE do not function as semiconductor devices. Therefore, originally, the dummy gate electrode DGE and the dummy gate pattern DGP need not be formed. However, performing oblique ion implantation in the state where the dummy gate pattern DGP is not formed is almost synonymous with the formation of the body region PB of the outermost MISFET 1Q in the state of opening width W5 as shown in FIG. 18.

In the first embodiment, the dummy gate electrode DGE is formed further outside the outermost MISFET 1Q. In other words, as shown in FIG. 11, the dummy gate pattern DGP is formed further outside the gate pattern GP for the outermost MISFET 1Q. Therefore, oblique ion implantation can be performed in the state of opening width W3 as shown in FIG. 18. Therefore, it is possible to sufficiently secure the number of ions injected into the channel region and suppress the reduction of threshold voltage, thus securing the reliability of the semiconductor device.

Furthermore, the opening widths W3 of the plurality of openings of the resist pattern RP1 are the same as each other. Therefore, in plan view, the width of the areas where the body region PB and the gate pattern GP overlap each other is constant under each gate pattern GP. Therefore, it is possible to suppress the variation in channel length of the plurality of MISFETs 1Q and also suppress the variation in impurity profile of the channel regions of the plurality of MISFETs 1Q.

Furthermore, as shown in FIG. 2, the plurality of source regions NS are formed to be separated from each other in the Y direction. It is preferable that the variation in impurity profile across the plurality of channel regions between the plurality of source regions NS and the drain region ND is suppressed.

Therefore, at the time of FIG. 11, it is preferable that the width of the dummy gate pattern DGP in the Y direction is greater than the width of the drain region ND formed in a later manufacturing step. Finally, as shown in FIG. 2, it is preferable that the width W1 of the dummy gate electrode DGE in the Y direction is greater than the width W2 of the drain region ND.

The width W2 of the drain region ND can also be understood using the source region NS as follows. As shown in FIG. 2, the plurality of source regions NS include a source region NS1 located at one outermost in the Y direction and another source region NS2 located at the other outermost in the Y direction. In other words, the plurality of source regions NS include the source region NS1 and the source region NS2, which are the farthest apart from each other in the Y direction. The source region NS1 has an outermost end portion NS1e, which is the farthest from the source region NS2 in the Y direction. The source region NS2 has an outermost end portion NS2e, which is the farthest from the source region NS1 in the Y direction. In the Y direction, the width of the dummy gate electrode DGE is greater than the distance from the outermost end portion NS1e to the outermost end portion NS2e.

### FIRST MODIFIED EXAMPLE

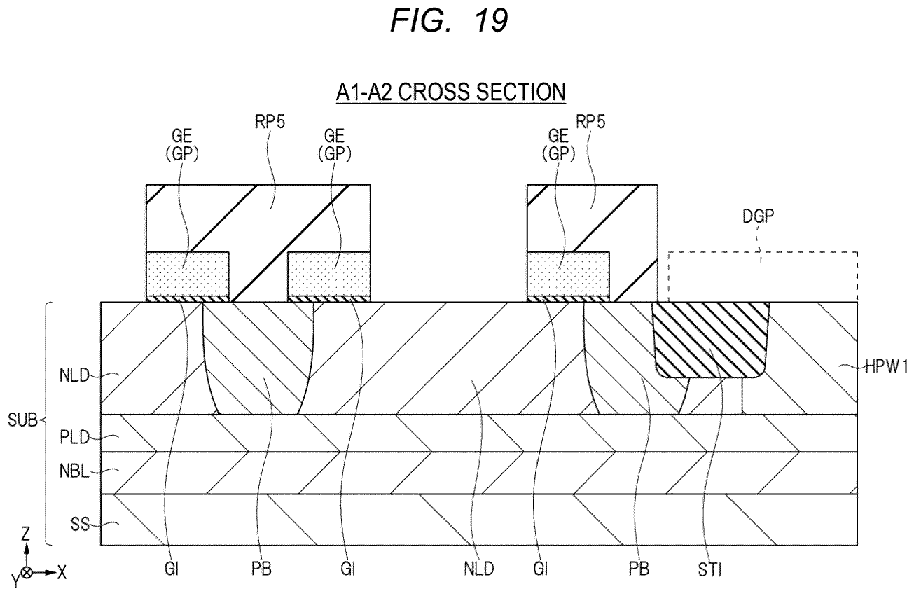

Hereinafter, a semiconductor device according to the first modified example of the first embodiment will be described with reference to FIG. 19. It should be noted that the following description will mainly address the differences from the first embodiment, and descriptions of aspects overlapping with the first embodiment will be omitted.

FIG. 19 shows a manufacturing step that follows the process of FIG. 11 and is performed instead of the manufacturing step of FIG. 12. In the first embodiment, as shown in FIG. 12, a part of the dummy gate pattern DGP is processed using the resist pattern RP2 to form the dummy gate electrode DGE. In the first modified example, as shown in FIG. 19, the dummy gate pattern DGP is completely removed using a resist pattern RP5.

As shown in FIG. 19, first, the resist pattern RP5 is formed to cover a part of the gate pattern GP located on the gate insulating film GI, the body region PB, and a part of the element isolation portion STI exposed from the dummy gate pattern DGP. In order to completely remove the dummy gate pattern DGP and avoid etching the semiconductor substrate SUB, the edges of the resist pattern RP5 are positioned on the portion of the element isolation portion STI that is located between the dummy gate pattern DGP and the body region PB.

Next, by performing anisotropic etching treatment using the resist pattern RP5 as a mask, the gate pattern GP and the dummy gate pattern DGP exposed from the resist pattern RP5 are selectively removed to form the gate electrode GE from the gate pattern GP. Since the dummy gate pattern DGP is completely removed, the dummy gate electrode DGE is not formed. Thereafter, the resist pattern RP5 is removed by ashing.

Thus, the dummy gate pattern DGP may be removed after forming the body region PB. The subsequent manufacturing steps are the same as those from FIG. 13 to FIG. 16.

### SECOND MODIFIED EXAMPLE

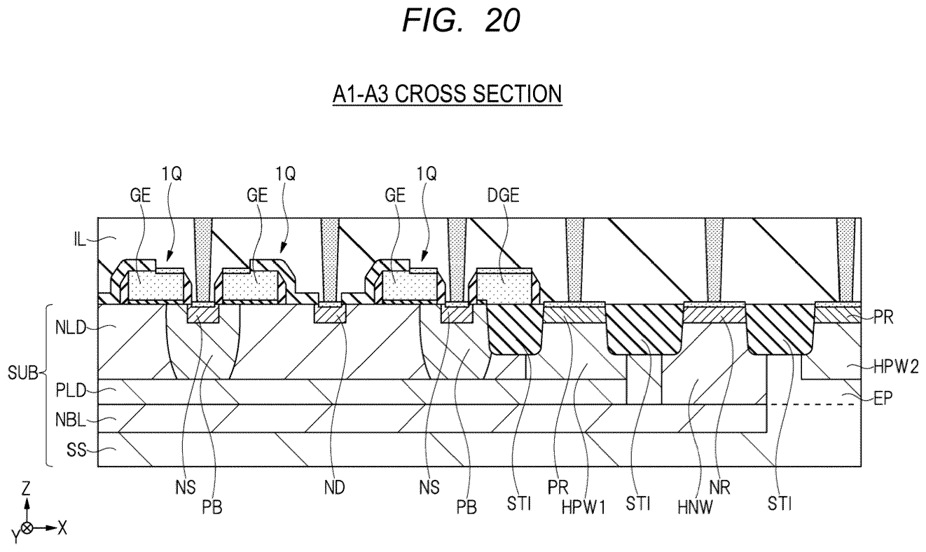

Hereinafter, a semiconductor device according to the second modified example of the first embodiment will be described with reference to FIGS. 20 to 22. It should be noted that the following description will mainly address the differences from the first embodiment, and descriptions of aspects overlapping with the first embodiment will be omitted.

In the first embodiment, the dummy gate electrode DGE is formed on the element isolation portion STI. In the second modified example, as shown in FIG. 20, the dummy gate electrode DGE is formed not only on the element isolation portion STI but also on the gate insulating film. In order to form the dummy gate electrode DGE as such, the dummy gate pattern DGP is formed on the element isolation portion STI and on the gate insulating film.

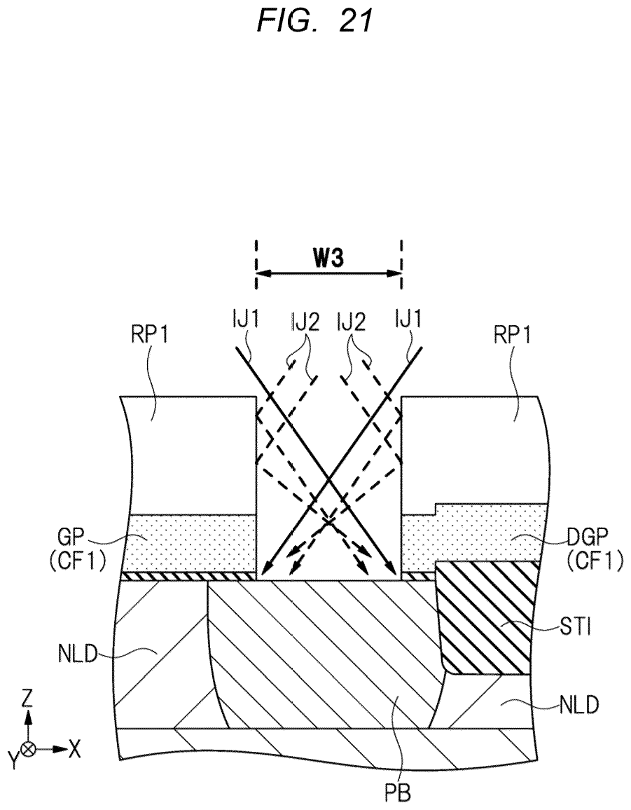

FIG. 21 shows a manufacturing step corresponding to the manufacturing steps of FIGS. 9 and 11. As shown in FIG. 21, the resist pattern RP1 is formed to expose a part of the conductive film CF1 located on the gate insulating film GI on the conductive film CF1. The resist pattern RP1 of the second modified example differs from the first embodiment in that it covers the conductive film CF1 located on the element isolation portion STI and the boundary between the element isolation portion STI and the semiconductor substrate SUB. In the second modified example, the opening width W3 of the resist pattern RP1 is the same as the opening width W3 of the first embodiment.

Next, by using the resist pattern RP1 as a mask and performing anisotropic etching treatment, the conductive film CF1 exposed from the resist pattern RP1 is selectively removed to form the gate pattern GP and the dummy gate pattern DGP from the conductive film CF1. The dummy gate pattern DGP is located on the gate insulating film GI and on the element isolation portion STI, crossing the boundary between the element isolation portion STI and the semiconductor substrate SUB. Then, by using the resist pattern RP1 as a mask and performing oblique ion implantation, the body region PB is formed. The body region PB is also formed in a part of the semiconductor substrate SUB located under the dummy gate pattern DGP.

As shown in FIG. 21, there may be a step between the upper surface of the semiconductor substrate SUB (the upper surface of the gate insulating film GI) and the upper surface of the element isolation portion STI. If such a step occurs, the symmetry of the injection positions of ions IJ1 and IJ2 injected from above the dummy gate pattern DGP towards the gate pattern GP and the injection positions of ions IJ1 and IJ2 injected from above the gate pattern GP towards the dummy gate pattern DGP tends to shift. That is, a difference in the amount of ion implantation near the gate pattern GP and near the dummy gate pattern DGP tends to occur.

As in the second modified example, by positioning the dummy gate pattern DGP also on the gate insulating film, it becomes unnecessary to consider the effect of the above-mentioned step, thereby improving the symmetry of the injection positions of ions IJ1 and IJ2 and allowing the ion implantation amount into the channel region to be uniformed.

Furthermore, because the step between the upper surface of the semiconductor substrate SUB and the upper surface of the element isolation portion STI does not occur, the conditions for ion implantation performed between the gate pattern GP and the dummy gate pattern DGP become the same as the conditions for ion implantation performed between a plurality of gate patterns GP. Therefore, it is possible to uniform the impurity profile in the channel region in the plurality of MISFETs 1Q.

Next, the difference between the second modified example and the first embodiment regarding the width in the X direction of the source region NS located between the gate pattern GP and the dummy gate pattern DGP in plan view is described.

In the first embodiment, the width in the X direction of the source region NS is mainly determined by the distance between the gate pattern GP and the element isolation portion STI. Therefore, if the formation position of the gate pattern GP varies, the distance between the gate pattern GP and the element isolation portion STI also varies, which may result in a reduction in the width of the source region NS in the X direction.

The width of the source region NS located between the gate pattern GP and the dummy gate pattern DGP in the X direction in plan view may be smaller than the width of the source region NS located between the plurality of gate patterns GP in the X direction in plan view. Consequently, in the MISFET 1Q using the source region NS located between the gate pattern GP and the dummy gate pattern DGP in plan view, there is a possibility of increased parasitic resistance and decreased on-current compared to other MISFETs 1Q.

As shown in FIG. 2, in the Y direction, the high concentration diffusion region PR are formed between adjacent source regions NS. Similar to the aforementioned source regions NS, there is a possibility that the width of the high concentration diffusion region PR located between the gate pattern GP and the dummy gate pattern DGP in the X direction in plan view may become smaller. Consequently, in the MISFET 1Q using the source region NS located between the gate pattern GP and the dummy gate pattern DGP in plan view, there is a possibility of increased resistance in the body region PB and decreased on-voltage endurance compared to other MISFETs 1Q.

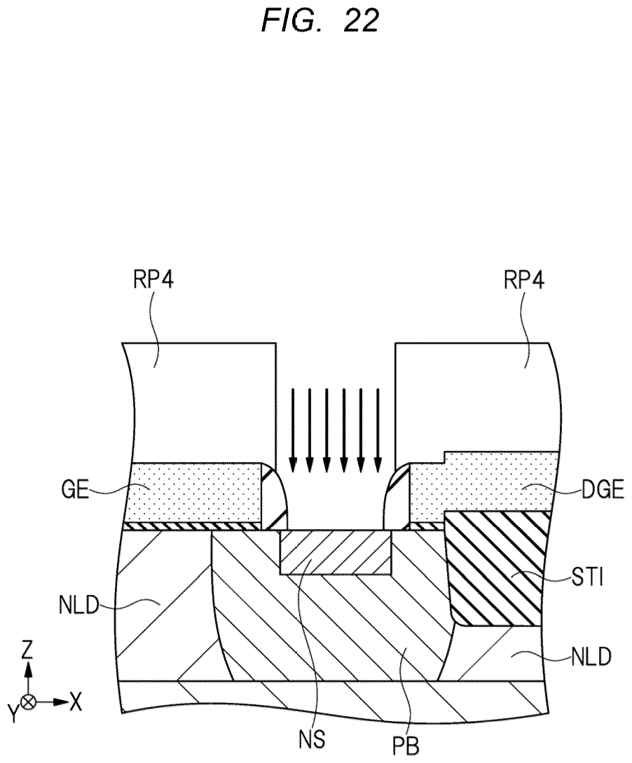

FIG. 22 shows a manufacturing step corresponding to the manufacturing step of FIG. 15. As shown in FIG. 22, the dummy gate pattern DGP is also located on the gate insulation film.

In the second modified example, the width of the source region NS and the high concentration diffusion region PR in the X direction is primarily determined by the distance between the gate pattern GP and the dummy gate pattern DGP. Even if the formation positions of the gate pattern GP and the dummy gate pattern DGP vary, the distance between the gate pattern GP and the dummy gate pattern DGP is constant.

That is, in the second modified example, the width of the source region NS located between the gate pattern GP and the dummy gate pattern DGP in the X direction in plan view becomes the same as the width of the source region NS located between the plurality of gate patterns GP in the X direction in plan view. Consequently, parasitic resistance is less likely to increase and on current is less likely to decrease in the MISFET 1Q using the source region NS located between the gate pattern GP and the dummy gate pattern DGP in plan view.

Furthermore, in the second modified example, the width of the high concentration diffusion region PR located between the gate pattern GP and the dummy gate pattern DGP in the X direction in plan view becomes the same as the width of the high concentration diffusion region PR located between the plurality of gate patterns GP in the X direction in plan view. Consequently, resistance in the body region PB is less likely to increase and on-voltage endurance is less likely to decrease in the MISFET 1Q using the source region NS located between the gate pattern GP and the dummy gate pattern DGP in plan view,.

As described above, the present invention has been specifically described based on embodiments. However, the present invention is not limited to these embodiments and can be variously modified without departing from the spirit thereof.

What is claimed is:

1. A method of manufacturing a semiconductor device, the method comprising:
(a) preparing a semiconductor substrate;
(b) after the (a), forming an element isolation portion in the semiconductor substrate;
(c) after the (b), forming a gate insulating film on the semiconductor substrate;
(d) after the (c), forming a first conductive film on the gate insulating film and on the element isolation portion;
(e) after the (d), forming a first resist pattern on the first conductive film, the first resist pattern having a first opening portion that exposes a part of the first conductive film located on the gate insulating film;
(f) after the (e), performing an anisotropic etching treatment using the first resist pattern as a mask to selectively remove the first conductive film exposed from the first resist pattern and to form a first gate pattern and a dummy gate pattern from the first conductive film;
(g) after the (f), performing an oblique ion implantation using the first resist pattern as a mask to form a first body region of a first conductivity type in a part of the semiconductor substrate located between the first gate pattern and the dummy gate pattern in plan view; and
(h) after the (g), removing the first resist pattern,
wherein the dummy gate pattern is located at least on the element isolation portion, and
wherein the first body region is formed in a part of the semiconductor substrate located under the first gate pattern.

2. The method according to claim 1,
wherein in the (e), the first resist pattern comprises a second opening portion that exposes another part of the first conductive film located on the gate insulating film,
wherein in the (f), a second gate pattern is formed from the remaining first conductive film,
wherein after the (f), the second gate pattern is located on the gate insulating film,
wherein in the (g), a second body region of the first conductivity type is formed in a part of the semiconductor substrate located between the first gate pattern and the second gate pattern in plan view,
wherein the second body region is formed in another part of the semiconductor substrate located under the first gate pattern and in a part of the semiconductor substrate located under the second gate pattern, and
wherein in a direction where the second gate pattern, the first gate pattern, and the dummy gate pattern are adjacent to each other, the shortest distance between the first gate pattern and the dummy gate pattern is the same as the shortest distance between the first gate pattern and the second gate pattern.

3. The method according to claim 1, comprising:
(i) after the (h), forming a second resist pattern covering a part of the first gate pattern located on the gate insulating film, the first body region, and a part of the dummy gate pattern located on the element isolation portion;
(j) after the (i), performing an anisotropic etching treatment using the second resist pattern as a mask to selectively remove the first gate pattern and the dummy gate pattern exposed from the second resist pattern, to form a first gate electrode from the remaining first gate pattern and to form a dummy gate electrode from the remaining dummy gate pattern; and
(k) after the (j), removing the second resist pattern,
wherein the dummy gate electrode is located at least on the element isolation portion.

4. The method according to claim 3, comprising:
(l) after the (k), forming a first source region of a second conductivity type opposite the first conductivity type in the first body region, and forming a first drain region of the second conductivity type in the semiconductor substrate,
wherein the first gate electrode, the dummy gate electrode, and the first drain region extend in a first direction in plan view,
wherein the first gate electrode is formed on a part of the semiconductor substrate located between the first source region and the first drain region in a second direction crossing the first direction in plan view, and
wherein in the first direction, a width of the dummy gate electrode is greater than a width of the first drain region.

5. The method according to claim 4,
wherein in the (l), the first source region comprising a plurality of first source regions, and the plurality of first source regions are formed in the first body region such that the plurality of first source regions are separated from each other in the first direction,
wherein the plurality of first source regions comprise one first source region and another first source region that are the farthest apart from each other in the first direction,
wherein the one first source region comprises a first outermost end portion that is the farthest in the first direction from the another first source region,
wherein the another first source region comprises a second outermost end portion that is the farthest in the first direction from the one first source region, and
wherein in the first direction, the width of the dummy gate electrode is greater than a distance from the first outermost end portion to the second outermost end portion.

6. The method according to claim 4,
wherein the semiconductor device comprises a MISFET,
wherein the MISFET comprises the first gate electrode, the first source region, and the first drain region,
wherein a part of the first body region located between the first source region and the first drain region and under the first gate electrode functions as a channel region of the MISFET, and
wherein during an operation of the MISFET, a gate voltage is supplied to the first gate electrode, and the dummy gate electrode is in an electrically floating state.

7. The method according to claim 4, comprising:
(m) before the (c), forming a first well region of the first conductivity type in the semiconductor substrate,
wherein the first well region extends in the first direction and in the second direction so as to be in contact with the element isolation portion and to surround at least the first gate electrode, the first source region, the first drain region, the first body region, the element isolation portion, and the dummy gate electrode in plan view.

8. The method according to claim 7, comprising:
(n) before the (c), forming a first impurity region of the first conductivity type in the semiconductor substrate at a position deeper than the element isolation portion,
wherein the first well region is formed from an upper surface of the semiconductor substrate to the position deeper than the element isolation portion and is in contact with the first impurity region, and
wherein the first body region is formed from the upper surface of the semiconductor substrate to the position deeper than the element isolation portion and is in contact with the first impurity region.

9. The method according to claim 4,
wherein in the (e), the first resist pattern comprises a second opening portion that exposes another part of the first conductive film located on the gate insulating film,
wherein in the (f), a second gate pattern is formed from the remaining first conductive film,
wherein in the (g), a second body region of the first conductivity type is formed in a part of the semiconductor substrate located between the first gate pattern and the second gate pattern in plan view,
wherein the second body region is formed in another part of the semiconductor substrate located under the first gate pattern and in a part of the semiconductor substrate located under the second gate pattern,
wherein in the second direction, the shortest distance between the first gate pattern and the dummy gate pattern is the same as the shortest distance between the first gate pattern and the second gate pattern,
wherein in the (i), the second resist pattern covers another part of the first gate pattern located on the gate insulating film, the second body region, and a part of the second gate pattern located on the gate insulating film,
wherein in the (j), the first gate pattern and the second gate pattern exposed from the second resist pattern are selectively removed to form the first gate electrode and a second gate electrode from the remaining first gate pattern and to form a third gate electrode from the remaining second gate pattern,
wherein in the (l), a second source region of the second conductivity type is formed in the second body region, and a second drain region of the second conductivity type is formed in the semiconductor substrate,
wherein the second gate electrode, the third gate electrode, and the second drain region extend in the first direction,
wherein the second gate electrode is formed on a part of the semiconductor substrate located between the first drain region and the second source region in the second direction,
wherein the third gate electrode is formed on a part of the semiconductor substrate located between the second drain region and the second source region in the second direction, and
wherein in the first direction, the width of the dummy gate electrode is greater than a width of the second drain region.

10. The method according to claim 1,
wherein the (b) comprises:
(b1) forming a trench in the semiconductor substrate;
(b2) forming an insulating film on the semiconductor substrate so as to fill the trench; and
(b3) removing the insulating film located outside the trench such that the insulating film buried in the trench remains.

11. The method according to claim 1, comprising:
(o) after the (h), forming a third resist pattern covering a part of the first gate pattern located on the gate insulating film, the first body region, and a part of the element isolation portion exposed from the dummy gate pattern; and
(p) after the (o), performing an anisotropic etching treatment using the third resist pattern as a mask to selectively remove the first gate pattern and the dummy gate pattern exposed from the third resist pattern and to form a first gate electrode from the first gate pattern.

12. The method according to claim 1,
wherein the element isolation portion surrounds the gate insulating film, the first gate pattern, and the first body region in plan view.

13. The method according to claim 1,
wherein the first gate pattern is located on the gate insulating film,
wherein the dummy gate pattern is located on the gate insulating film and the element isolation portion so as to cross a boundary between the element isolation portion and the semiconductor substrate, and
wherein the first body region is formed in a part of the semiconductor substrate located under the dummy gate pattern.

14. The method according to claim 3,
wherein the dummy gate electrode is formed on the element isolation portion and on the gate insulating film.
